(19) United States
(12) Patent Application Publication
(10) Pub. No.: US 2026/0343872 A1
(43) Pub. Date: Oct. 29, 2026

(54) SEMICONDUCTOR DEVICE INCLUDING BIT LINE AND GATE STRUCTURE

(71) Applicant: SAMSUNG ELECTRONICS CO., LTD., Suwon-si (KR)

(72) Inventors: Jongin Kang, Suwon-si (KR); Chan-sic Yoon, Suwon-si (KR)

(73) Assignee: SAMUSNG ELECTRONICS CO., LTD., Suwon-si (KR)

(21) Appl. No.: 19/395,709

(22) Filed: Nov. 20, 2025

(30) Foreign Application Priority Data
Apr. 25, 2025 (KR) 10-2025-0054751

(51) Int. Cl. H10B 12/00

(52) U.S. Cl. CPC H10B 12/50; H10B 12/09; H10B 12/482

(57) ABSTRACT

A semiconductor device includes a substrate including a cell region and a peripheral region, an active pattern on the cell region of the substrate, a bit line extending in a direction on the active pattern, and a peripheral gate structure on the peripheral region. The bit line includes a first conductive pattern connected to the active pattern and a first metal pattern on the first conductive pattern. The peripheral gate structure includes a peripheral gate dielectric layer on the peripheral region of the substrate, a peripheral conductive pattern on the peripheral gate dielectric layer and a peripheral metal pattern on the peripheral conductive pattern. A thickness of the peripheral metal pattern is greater than a thickness of the first metal pattern.

This patent application claims priority under 35 U.S.C. § 119 to and the benefit of Korean Patent Application No. 10-2025-0054751, filed on Apr. 25, 2025, in the Korean Intellectual Property Office, the disclosure of which is incorporated by reference herein in its entirety.

### BACKGROUND

The disclosure relates to a semiconductor device, and in particular, to a semiconductor device including a bit line on a cell region and a peripheral gate structure on a peripheral region.

Due to their small size, multifunctional characteristics, and/or low-cost manufacturing, semiconductor devices are being esteemed as important elements in the electronics industry. The semiconductor devices are classified into a semiconductor memory device for storing data, a semiconductor logic device for processing data, and a hybrid semiconductor device including a memory and logic elements.

With the recent trend of high speed and low power consumption of electronic devices, semiconductor devices in the electronic devices are also required to have high operating speeds and/or low operating voltages. In order to satisfy this requirement, it is necessary to increase an integration density of the semiconductor device. However, as the integration density of the semiconductor device increases, the semiconductor device may suffer from deteriorated electrical characteristics and low production yield. Accordingly, many studies are being conducted to improve the electrical characteristics and production yield of the semiconductor device.

### SUMMARY

Embodiments provide a semiconductor device capable of improving electrical characteristics.

According to an embodiment, a semiconductor device may include a substrate including a cell region and a peripheral region, an active pattern on the cell region of the substrate, a bit line extending in a direction on the active pattern, and a peripheral gate structure on the peripheral region, wherein the bit line may include a first conductive pattern connected to the active pattern and a first metal pattern on the first conductive pattern, wherein the peripheral gate structure may include a peripheral gate dielectric layer on the peripheral region of the substrate a peripheral conductive pattern on the peripheral gate dielectric layer and a peripheral metal pattern on the peripheral conductive pattern, and wherein a thickness of the peripheral metal pattern may be greater than a thickness of the first metal pattern.

According to an embodiment, a semiconductor device may include a substrate including a cell region and a peripheral region, an active pattern on the cell region of the substrate, word lines extending across the active pattern in a first direction, a bit line extending in a second direction intersecting the first direction on the word lines, a peripheral gate structure on the peripheral region, and a liner layer covering a sidewall and an upper surface of the peripheral gate structure, wherein the peripheral gate structure may include a peripheral gate dielectric layer on the peripheral region of the substrate, a peripheral gate electrode on the peripheral gate dielectric layer, a peripheral capping pattern on the peripheral gate electrode, and a buffer pattern between the peripheral capping pattern and the peripheral gate electrode.

According to an embodiment, a semiconductor device may include a substrate including a cell region and a peripheral region, an active pattern on the cell region of the substrate, word lines extending across the active pattern a first direction, a bit line structure extending in a second direction intersecting the first direction on the word lines, the bit line structure including a bit line and a bit line capping pattern on the bit line, a node contact connected to the active pattern, a landing pad connected to the node contact and a peripheral gate structure on the peripheral region, wherein the bit line may include a first conductive pattern extending in the second direction on the active pattern and a first metal pattern on the first conductive pattern, wherein the peripheral gate structure may include a peripheral gate dielectric layer on the peripheral region of the substrate, a peripheral conductive pattern on the peripheral gate dielectric layer, a peripheral metal pattern on the peripheral conductive pattern, a peripheral capping pattern on the peripheral metal pattern and a buffer pattern between the peripheral capping pattern and the peripheral metal pattern, and wherein a thickness of the peripheral metal pattern may be greater than a thickness of the first metal pattern.

According to an embodiment, a method of manufacturing a semiconductor device may include providing a substrate including a cell region and a peripheral region, forming a first device isolation layer defining an active pattern on the cell region, forming a peripheral gate dielectric layer at least partially covering the peripheral region of the substrate, forming a peripheral conductive layer on the peripheral gate dielectric layer, forming a first preliminary conductive layer on the first device isolation layer and the active pattern, forming a metal layer covering the first preliminary conductive layer and the peripheral gate dielectric layer, forming a mask pattern partially covering the metal layer on the peripheral region, etching a portion of the metal layer using the mask pattern as an etching mask to form a first metal layer and a second metal layer connected to the first metal layer and having a different thickness from the first metal layer, patterning the peripheral conductive layer and the second metal layer to form a peripheral gate electrode on the peripheral region, and patterning the first preliminary conductive layer and the first metal layer to form a bit line connected to the active pattern.

According to some embodiments, forming the first preliminary conductive layer may include partially etching the active pattern to form a recess region, and depositing a conductive material to fill the recess region.

According to some embodiments, a thickness of the first metal layer may be smaller than a thickness of the second metal layer.

According to some embodiments, the first metal layer may not expose the first preliminary conductive layer on the cell region.

### BRIEF DESCRIPTION OF DRAWINGS

FIG. 1 is a plan view of a semiconductor device according to some embodiments.

FIG. 2 is an enlarged view of a portion “E1” of FIG. 1.

FIG. 3A is a cross-sectional view taken along line A-A’ in FIG. 2.

FIG. 3B is a cross-sectional view taken along line B-B’ of FIG. 2.

FIGS. 4-11 are cross-sectional views illustrating a method of manufacturing a semiconductor device according to some embodiments.

### DETAILED DESCRIPTION

The embodiments described herein are non-limiting example embodiments, and thus, the disclosure is not limited thereto and may be realized in various other forms. Hereinafter, a semiconductor device and a method for manufacturing the same according to embodiments will be described in detail with reference to the drawings.

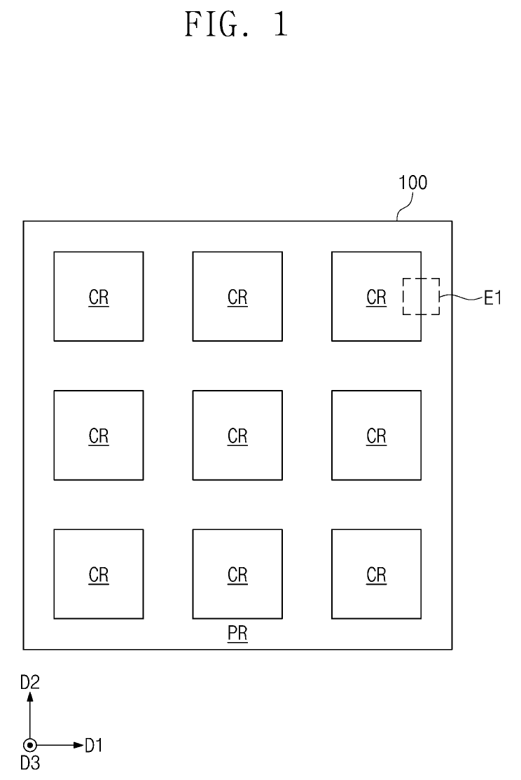

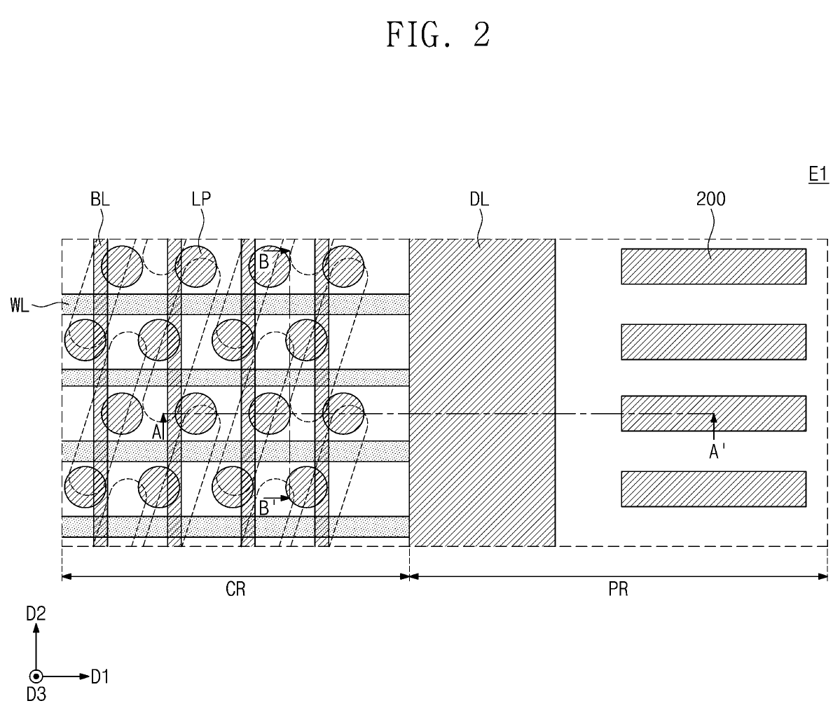

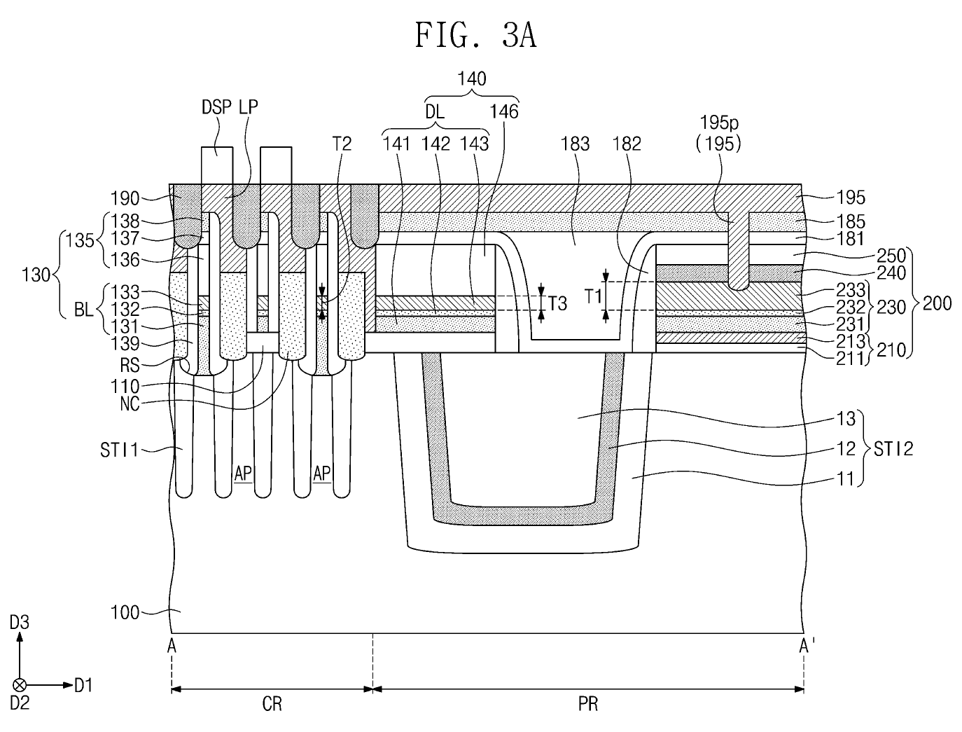

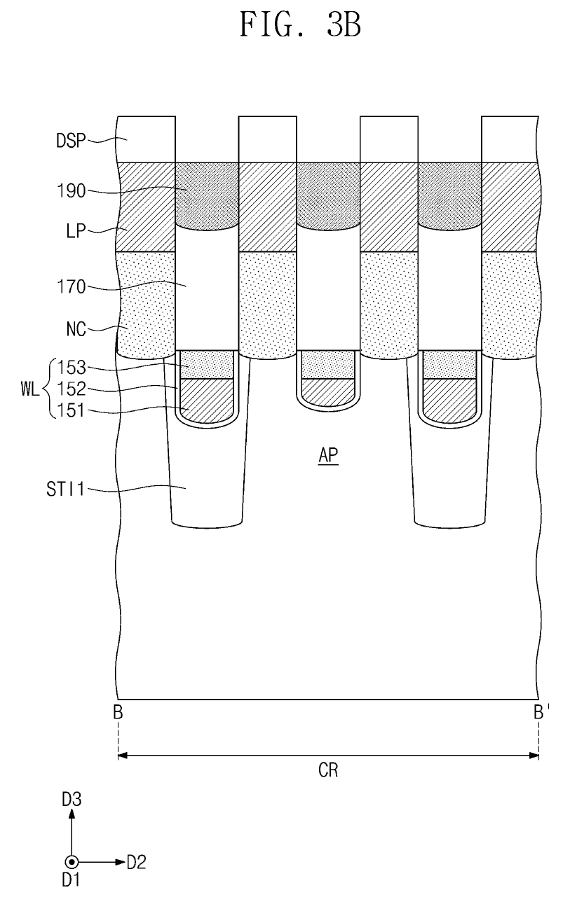

FIG. 1 is a plan view of a semiconductor device according to some embodiments. FIG. 2 is an enlarged view of a portion “E1” of FIG. 1. FIG. 3A is a cross-sectional view taken along line A-A’ in FIG. 2. FIG. 3B is a cross-sectional view taken along line B-B’ of FIG. 2.

Referring to FIGS. 1, 2, 3A, and 3B, a semiconductor device may include a substrate 100. In some embodiments, the substrate 100 may be a semiconductor substrate. For example, the substrate 100 may include silicon (Si), germanium (Ge), silicon-germanium (SiGe), gallium phosphide (GaP), or gallium arsenide (GaAs). In some embodiments, the substrate 100 may be a silicon-on-insulator (SOI) substrate or a germanium-on-insulator (GOI) substrate. The substrate 100 may have a plate shape extending in a first direction D1 and a second direction D2. The first direction D1 and the second direction D2 may intersect with each other. For example, the first direction D1 and the second direction D2 may be horizontal directions that are orthogonal to each other.

The substrate 100 may include a cell region CR and a peripheral region PR. The peripheral region PR may surround the cell region CR.

Active patterns AP may be disposed on the cell region CR of the substrate 100. Upper portions of the cell region CR of the substrate 100 protruding in a third direction D3 may be defined as the active patterns AP. The third direction D3 may intersect the first direction D1 and the second direction D2. For example, the third direction D3 may be a vertical direction orthogonal to the first direction D1 and the second direction D2. For example, the third direction D3 may be a direction perpendicular to a bottom surface (or lower surface) of the substrate 100. The active patterns AP may be spaced apart from each other.

A first device isolation layer STI1 defining the active patterns AP may be provided. The first device isolation layer STI1 may be disposed on the cell region CR of the substrate 100. Each of the active patterns AP may be surrounded by the first device isolation layer STI1.

A second device isolation layer STI2 may be disposed on the peripheral region PR of the substrate 100. The second device isolation layer STI2 may surround the cell region CR of the substrate 100. In some embodiments, the second device isolation layer STI2 and the first device isolation layer STI1 may have an integral structure connected to each other without a boundary.

The first device isolation layer STI1 may include an insulating material. For example, the first device isolation layer STI1 may include at least one of silicon oxide or silicon nitride. The second device isolation layer STI2 may include a first isolation insulating layer 11, a second isolation insulating layer 12 on the first isolation insulating layer 11, and a third isolation insulating layer 13 on the second isolation insulating layer 12. For example, the first isolation insulating layer 11 may include silicon oxide, the second isolation insulating layer 12 may include silicon nitride, and the third isolation insulating layer 13 may include silicon oxide. This excludes Si₃N₄ which is most commonly used silicon nitride for an isolation structure . So please do not use this chemical symbol throughout

Word lines WL extending in the first direction D1 may be provided. The word lines WL may be arranged in the second direction D2. The word lines WL may be disposed on the cell region CR of the substrate 100. The word lines WL may be disposed on the first device isolation layer STI1 and the active patterns AP. The word line WL may be a gate structure embedded in the active patterns AP and the first device isolation layer STI1. The active patterns AP may include impurity regions. A cell transistor may be defined by the word line WL and the active pattern AP.

Each of the word lines WL may include a gate insulating layer 152 on the active pattern AP, a gate electrode 151 on the gate insulating layer 152, and a gate capping layer 153 on the gate electrode 151. The gate insulating layer 152 and the gate capping layer 153 may include an insulating material. For example, the gate insulating layer 152 may include silicon oxide, and the gate capping layer 153 may include silicon nitride (SiNₓ). The gate electrode 151 may include a conductive material.

A lower insulating layer 110 may be disposed on the first device isolation layer STI1 and the second device isolation layer STI2. The lower insulating layer 110 may include an insulating material. For example, the lower insulating layer 110 may include a plurality of multilayers including silicon oxide and silicon nitride (SiNₓ).

A bit line structure 130 extending in the second direction D2 may be disposed on the active pattern AP and the lower insulating layer 110. The bit line structure 130 may be disposed on the cell region CR of the substrate 100. The bit line structures 130 may be spaced apart from each other along the first direction D1. The bit line structure 130 may be disposed on the lower insulating layer 110 and the active pattern AP. The bit line structure 130 may be connected (e.g., electrically connected) to the active pattern AP.

The bit line structure 130 may include a bit line BL and a bit line capping pattern 135. The bit line BL may include a first conductive pattern 131, a first barrier pattern 132, and a first metal pattern 133 sequentially stacked with each other.

The first conductive pattern 131 may be in contact with the active pattern AP. For example, the bit line BL may be connected (e.g., electrically connected) to the active pattern AP through the first conductive pattern 131. The first conductive pattern 131 may be disposed in a recess region RS formed in an upper portion of the substrate 100 and exposing a top surface (or upper surface) of the active pattern AP. The recess region RS may have an elliptical shape in a plan view, and a width of the recess region RS in a short axis direction may be greater than a width of the bit line structures 130. For example, the first conductive pattern 131 may include polysilicon.

The first barrier pattern 132 may be disposed on the first conductive pattern 131. The first barrier pattern 132 may include titanium (Ti) and/or titanium nitride (TiN). In some embodiment, a silicide pattern may be disposed between the first barrier pattern 132 and the first conductive pattern 131.

The first metal pattern 133 may be disposed on the first barrier pattern 132. The first metal pattern 133 may extend in the second direction D2 on the first barrier pattern 132. The first metal pattern 133 may include a metal. For example, the first metal pattern 133 may include at least one of tungsten (W) or cobalt (Co).

The bit line capping pattern 135 may be disposed on the bit line BL. The bit line capping pattern 135 may cover a top surface (or upper surface) of the first metal pattern 133. The bit line capping pattern 135 may include a first capping pattern 136, a second capping pattern 137, and a third capping pattern 138 sequentially stacked along the third direction D3. For example, each of the first to third capping patterns 136, 137, and 138 may include at least one of silicon oxide or silicon nitride (SiNₓ).

A bit line spacer 139 may fill a remaining portion of the recess region RS. For example, the bit line spacer 139 may cover a sidewall of the first conductive pattern 131, a sidewall of the first barrier pattern 132, a sidewall of the first metal pattern 133, and a sidewall of the first capping pattern 136. The bit line spacer 139 may include an insulating material. In some embodiments, the bit line spacer 139 may include a plurality of insulating layers.

A node contact NC may be provided. The node contact NC may be disposed on the cell region CR of the substrate 100. The node contact NC may be disposed on the active pattern AP. The node contact NC may be connected (e.g., electrically connected) to the active pattern AP. The node contacts NC may be disposed between the bit line structures 130. The node contact NC may be disposed on a sidewall of the bit line structure 130. The node contact NC may include a conductive material. For example, the node contact NC may include polysilicon.

A landing pad LP may be provided. The landing pad LP may be disposed on the node contact NC. The landing pad LP may be connected (e.g., electrically connected) to the node contact NC. The landing pad LP may include a conductive material. For example, the landing pad LP may include a metal. In some embodiments, a metal silicide layer may be disposed between the node contact NC and the landing pad LP. In some embodiments, a barrier layer may be disposed between the node contact NC and the landing pad LP.

An upper insulating pattern 190 may be disposed between the landing pads LP. The upper insulating pattern 190 may surround sidewalls of the landing pads LP. The upper insulating pattern 190 may fill the space between the landing pads LP. For example, the upper insulating pattern 190 may include at least one of silicon oxide or silicon nitride (SiNₓ).

An insulating fence 170 may be provided. The insulating fence 170 may be disposed on the gate capping layer 153 of the word line WL. The insulating fence 170 may be disposed between the node contacts NC adjacent to each other in the second direction D2. The insulating fence 170 may be disposed between the bit line structures 130 adjacent to each other in the first direction D1. The insulating fence 170 may include an insulating material.

A data storage pattern DSP may be provided. The data storage pattern DSP may be connected (e.g., electrically connected) to the active pattern AP through the landing pad LP and the node contact NC. In some embodiments, the data storage pattern DSP may be a capacitor including a lower electrode, a dielectric layer, and an upper electrode. For example, a semiconductor device including the data storage pattern DSP may be a dynamic random access memory (DRAM). In some embodiments, the data storage pattern DSP may include a magnetic tunnel junction pattern. For example, a semiconductor device including the data storage pattern DSP may be a magnetic random access memory (MRAM). In some embodiments, the data storage pattern DSP may include a phase change material or a variable resistance material. For example, a semiconductor device including the data storage patterns DSP may be a phase-change random access memory (PRAM) or a resistive random access memory (ReRAM). In some embodiments, the data storage pattern DSP may include various structures and/or materials capable of storing data.

A dummy line structure 140 may be provided. The dummy line structure 140 may be disposed on the peripheral region PR of the substrate 100. The dummy line structure 140 may extend in the second direction D2. The dummy line structure 140 may be disposed between the bit line structure 130 and a peripheral gate structure 200 described below. The dummy line structure 140 may be horizontally spaced from the bit line structure 130 and the peripheral gate structure 200.

The dummy line structure 140 may include a dummy line DL on the lower insulating layer 110 and a dummy capping pattern 146. The dummy line DL may include a second conductive pattern 141, a second barrier pattern 142, and a second metal pattern 143. The second conductive pattern 141, the second barrier pattern 142, and the second metal pattern 143 may be sequentially stacked on the lower insulating layer 110 along the third direction D3.

The second conductive pattern 141 and the first conductive pattern 131 may include the same material. The second barrier pattern 142 and the first barrier pattern 132 may include the same material. The second metal pattern 143 and the first metal pattern 133 may include the same metal. For example, the second conductive pattern 141 may include polysilicon. For example, the second barrier pattern 142 may include titanium (Ti) and/or titanium nitride (TiN). For example, the second metal pattern 143 may include at least one of tungsten (W) or cobalt (Co). The dummy capping pattern 146 may include an insulating material. For example, the dummy capping pattern 146 may include at least one of silicon oxide or silicon nitride (SiNₓ).

The peripheral gate structure 200 may be disposed on the peripheral region PR of the substrate 100. In some embodiments, the peripheral gate structure 200 may function as a sub-word line driver, or may function as a gate of a transistor, which is included in a sense amplifier.

The peripheral gate structure 200 may include a peripheral gate dielectric layer 210, a peripheral gate electrode 230, a buffer pattern 240, and a peripheral capping pattern 250. The peripheral gate dielectric layer 210 may be disposed on the peripheral region PR of the substrate 100. The peripheral gate dielectric layer 210 may include a peripheral insulating layer 211 covering a top surface (or upper surface) of the substrate 100 and a high dielectric layer 213 on the peripheral insulating layer 211. For example, the peripheral insulating layer 211 may include silicon oxide, and the high dielectric layer 213 may include at least one of hafnium oxide, zirconium oxide, aluminum oxide, or lanthanum oxide.

The peripheral gate electrode 230 may be disposed on the peripheral gate dielectric layer 210. The peripheral gate electrode 230 may include a peripheral conductive pattern 231, a peripheral barrier pattern 232, and a peripheral metal pattern 233. The peripheral conductive pattern 231 may be in contact with a top surface (or upper surface) of the high dielectric layer 213. The peripheral conductive pattern 231 may include, for example, doped polysilicon. The peripheral barrier pattern 232 may be disposed on the peripheral conductive pattern 231. The peripheral barrier pattern 232 may cover a top surface (or upper surface) of the peripheral conductive pattern 231. For example, the peripheral barrier pattern 232 may include titanium (Ti) and/or titanium nitride (TiN). The peripheral metal pattern 233 may cover a top surface (or upper surface) of the peripheral barrier pattern 232. For example, the peripheral metal pattern 233 may include the same metal as the first metal pattern 133, and may include at least one of tungsten (W) or cobalt (Co).

The buffer pattern 240 may be disposed on the peripheral gate electrode 230. For example, the buffer pattern 240 may be disposed between the peripheral gate electrode 230 and the peripheral capping pattern 250 described below. The buffer pattern 240 may be in contact with a top surface (or upper surface) of the peripheral gate electrode 230 and cover the top surface of the peripheral gate electrode 230. For example, the buffer pattern 240 may include silicon nitride (SiNₓ).

A bottom surface (or lower surface) of the buffer pattern 240 may be positioned at a higher level than a top surface (or upper surface) of the dummy line DL or a top surface (or upper surface) of the second metal pattern 143. The bottom surface of the buffer pattern 240 may be positioned at a higher level than a top surface (or upper surface) of the bit line BL. A top surface (or upper surface) of the buffer pattern 240 may be positioned at a lower level than a top surface (or upper surface) of the dummy capping pattern 146. The top surface of the buffer pattern 240 may be positioned at a lower level than a top surface (or upper surface) of the bit line capping pattern 135.

The peripheral capping pattern 250 may be disposed on the buffer pattern 240. The peripheral capping pattern 250 may cover the top surface of the buffer pattern 240. The peripheral capping pattern 250 may include, for example, at least one of silicon oxide or silicon nitride (SiNₓ).

The peripheral metal pattern 233 of the peripheral gate electrode 230 may have a first thickness T1, and the first metal pattern 133 of the bit line BL may have a second thickness T2. The first thickness T1 of the peripheral metal pattern 233 may be referred to as a length of the peripheral metal pattern 233 in the third direction D3. The second thickness T2 of the first metal pattern 133 may be referred to as a length of the first metal pattern 133 in the third direction D3. The first thickness T1 of the peripheral metal pattern 233 may be greater than the second thickness T2 of the first metal pattern 133.

A top surface (or upper surface) of the peripheral metal pattern 233 may be positioned at a higher level than a top surface (or upper surface) of the first metal pattern 133. For example, a distance between the top surface of the peripheral metal pattern 233 and the bottom surface of the substrate 100 may be greater than a distance between the top surface of the first metal pattern 133 and the bottom surface the substrate 100.

The second metal pattern 143 of the dummy line DL may have a third thickness T3. The third thickness T3 of the second metal pattern 143 may be referred to as a length of the second metal pattern 143 in the third direction D3. The third thickness T3 of the second metal pattern 143 may be less than the first thickness T1 of the peripheral metal pattern 233. The third thickness T3 of the second metal pattern 143 may be substantially the same as the second thickness T2 of the first metal pattern 133.

A top surface (or upper surface) of the second metal pattern 143 may be substantially coplanar with the top surface of the first metal pattern 133. For example, a distance between the top surface of the second metal pattern 143 and the bottom surface of the substrate 100 may be substantially the same as a distance between the top surface of the first metal pattern 133 and the bottom surface of the substrate 100.

A top surface (or upper surface) of the peripheral gate structure 200 may be coplanar with a top surface of the dummy line structure 140. For example, a top surface (or upper surface) of the peripheral capping pattern 250 may be coplanar with a top surface (or upper surface) of the dummy capping pattern 146. A thickness of the dummy capping pattern 146 may be greater than a thickness of the peripheral capping pattern 250.

According to an embodiment, since the second thickness T2 of the first metal pattern 133 is formed to be small, a parasitic capacitance of the bit line BL may be reduced. Accordingly, a capacitance of the data storage pattern DSP may increase compared to the parasitic capacitance of the bit line BL. As a result, sensing margin of the semiconductor device may be improved.

Since the first thickness T1 of the peripheral metal pattern 233 is formed to be large, a resistance of the peripheral metal pattern 233 may be reduced. Therefore, signal speed transmitted to the peripheral gate structure 200 may be improved. Furthermore, a semiconductor device with improved electrical characteristics may be provided.

A liner layer 181 may be disposed on the peripheral region PR of the substrate 100. The liner layer 181 may be disposed on the dummy line structure 140, the peripheral gate structure 200, and peripheral spacers 182. The liner layer 181 may cover sidewalls and a top surface (or upper surface) of the dummy line structure 140, and sidewalls and a top surface (or upper surface) of the peripheral gate structure 200. The liner layer 181 may include an insulating material, and may include, for example, at least one of silicon oxide or silicon nitride (SiNₓ).

The peripheral spacers 182 on the peripheral region PR of the substrate 100 may be provided. The peripheral spacers 182 may be disposed between the liner layer 181 and the peripheral gate structure 200, and between the liner layer 181 and the dummy line structure 140. The peripheral spacers 182 may be disposed on sidewalls of the dummy line structure 140 and sidewalls of the peripheral gate structure 200. The peripheral spacers 182 may cover the sidewalls of the dummy line DL and the dummy capping pattern 146. The peripheral spacers 182 may cover a sidewall of the peripheral gate dielectric layer 210, a sidewall of the peripheral gate electrode 230, a sidewall of the buffer pattern 240, and a sidewall of the peripheral capping pattern 250. The peripheral spacers 182 may include an insulating material, and may include, for example, at least one of silicon oxide or silicon nitride (SiNₓ).

A filling insulating layer 183 may be disposed between the dummy line structure 140 and the peripheral gate structure 200. The filling insulating layer 183 may fill a space between the dummy line structure 140 and the peripheral gate structure 200 on the liner layer 181. The filling insulating layer 183 may include an insulating material, and may include, for example, at least one of silicon oxide or silicon nitride (SiNₓ).

An interlayer insulating layer 185 may be disposed on the liner layer 181 and the filling insulating layer 183. The interlayer insulating layer 185 may cover a top surface (or upper surface) of the liner layer 181 and a top surface (or upper surface) of the filling insulating layer 183. A top surface (or upper surface) of the interlayer insulating layer 185 may be substantially coplanar with a top surface (or upper surface) of the bit line capping pattern 135. For example, the interlayer insulating layer 185 may include at least one of silicon oxide or silicon nitride (SiNₓ).

Conductive structures 195 may be disposed on the interlayer insulating layer 185. The conductive structures 195 may be disposed on the peripheral region PR of the substrate 100. The conductive structures 195 may include a conductive material. For example, the conductive structures 195 may include a metal.

At least one of the conductive structures 195 may include a protrusion 195p connected to the peripheral gate structure 200. The protrusion 195p may penetrate the interlayer insulating layer 185 and the liner layer 181 to connect (e.g., electrically connect) to the peripheral gate electrode 230 of the peripheral gate structure 200. The protrusion 195p may penetrate the peripheral capping pattern 250 and the buffer pattern 240 of the peripheral gate structure 200. The protrusion 195p may be vertically spaced apart from the peripheral barrier pattern 232 and the peripheral conductive pattern 231.

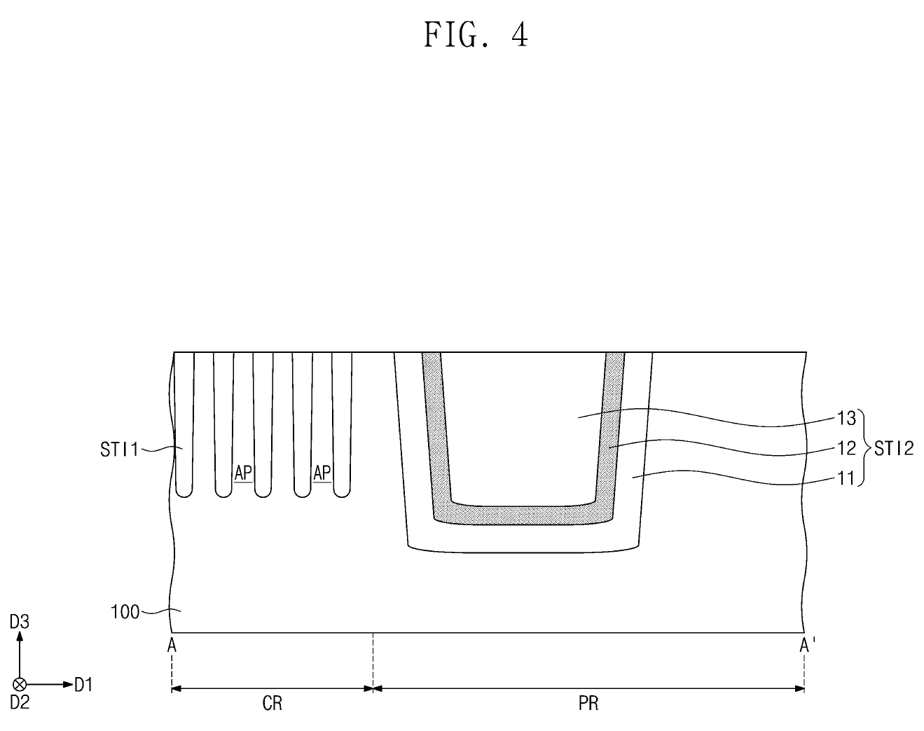

FIGS. 4-11 are cross-sectional views illustrating a method of manufacturing a semiconductor device according to some embodiments.

Referring to FIG. 4, a substrate 100 including a cell region CR and a peripheral region PR may be provided. A first device isolation layer STI1 defining active patterns AP may be formed on the cell region CR of the substrate 100. The first device isolation layer STI1 may be formed by forming trenches on the cell region CR of the substrate 100 and by filling the trenches with an insulating material.

A second device isolation layer STI2 may be formed on the peripheral region PR of the substrate 100. The second device isolation layer STI2 may be formed by forming trenches on the peripheral region PR of the substrate 100 and by sequentially depositing a first insulating material 11, a second insulating material 12, and a third insulating material 13 in the trenches. For example, the first insulating material may include silicon oxide, the second insulating material may include silicon nitride (SiNₓ), and the third insulating material may include silicon oxide.

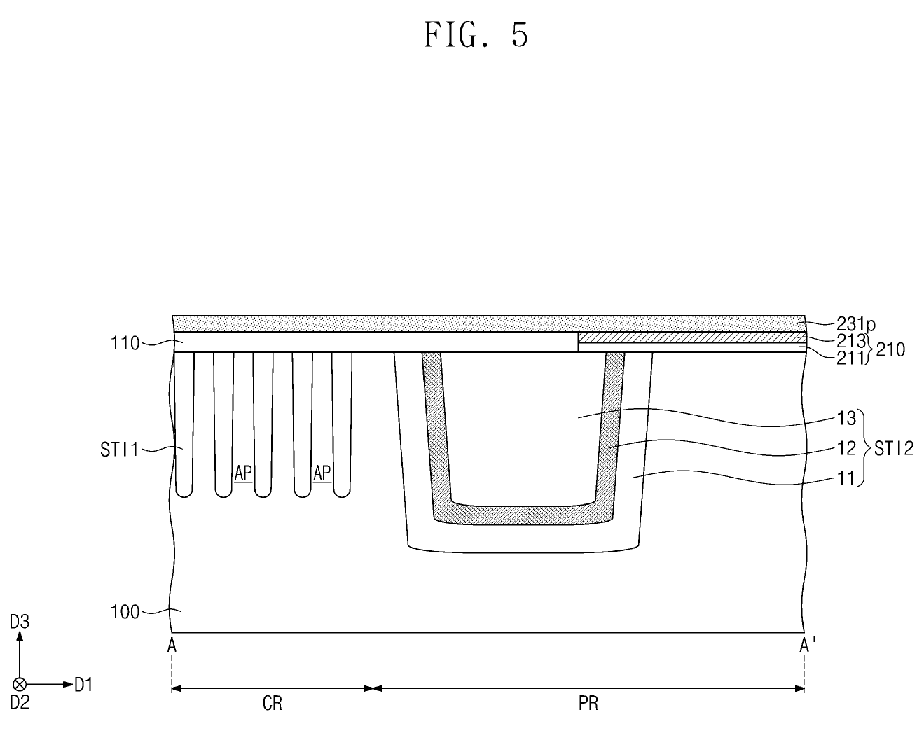

Referring to FIG. 5, a peripheral gate dielectric layer 210 may be formed on the peripheral region PR of the substrate 100. The peripheral gate dielectric layer 210 may be formed by sequentially depositing a peripheral insulating layer 211 on the substrate 100 and a high dielectric layer 213 on the peripheral insulating layer 211. The peripheral gate dielectric layer 210 may cover at least a portion of the peripheral region PR of the substrate 100.

A lower insulating layer 110 may be formed on the cell region CR of the substrate 100. The lower insulating layer 110 may cover the first device isolation layer STI1 and the active patterns AP of the substrate 100. For example, the lower insulating layer 110 may be formed by sequentially depositing a plurality of insulating materials.

A preliminary peripheral conductive layer 231p may be formed on the lower insulating layer 110 and the peripheral gate dielectric layer 210. The preliminary peripheral conductive layer 231p may cover top surfaces (or upper surfaces) of the lower insulating layer 110 and the peripheral gate dielectric layer 210. The preliminary peripheral conductive layer 231p may include, for example, doped polysilicon.

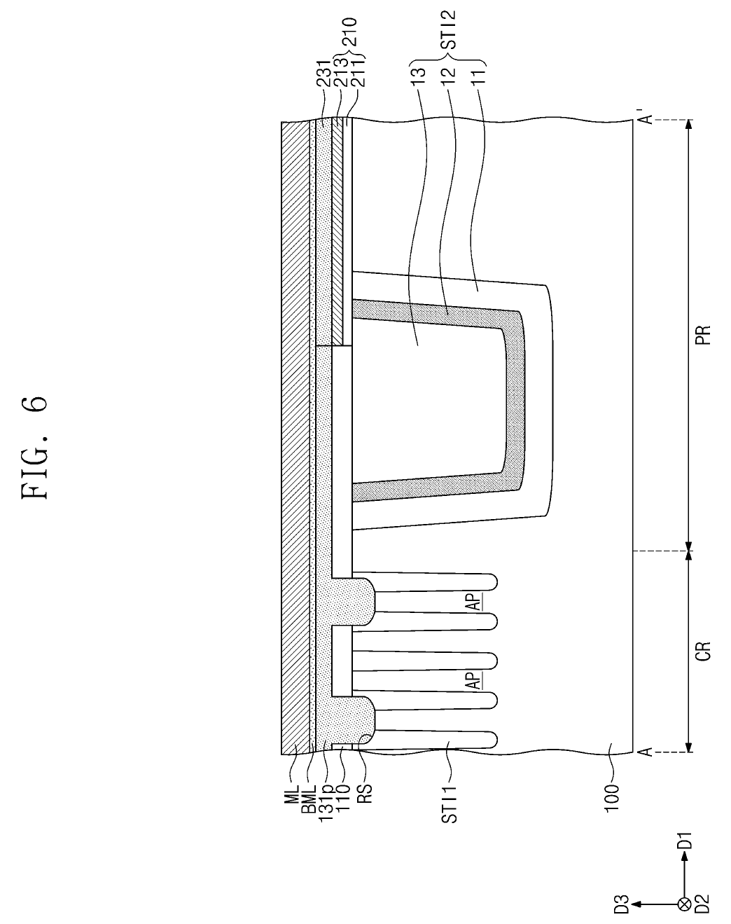

Referring to FIGS. 5 and 6, the preliminary peripheral conductive layer 231p may be partially removed, so that the top surface of the lower insulating layer 110 may be exposed. A remaining portion of the preliminary peripheral conductive layer 231p may be referred to as a peripheral conductive pattern 231.

Recess regions RS may be formed by patterning the substrate 100 and the lower insulating layer 110 on the cell region CR of the substrate 100. For example, each of the recess regions RS may have an elliptical shape in a plan view. For example, the recess regions RS may be arranged in a zigzag shape or a honeycomb shape in a plan view.

A first preliminary conductive layer 131p may be formed on the cell region CR of the substrate 100. The first preliminary conductive layer 131p may fill the recess regions RS and may be disposed on the lower insulating layer 110. A portion of the first preliminary conductive layer 131p may extend onto the peripheral region PR. The first preliminary conductive layer 131p may include, for example, polysilicon.

A barrier layer BML may be formed on the first preliminary conductive layer 131p and the peripheral gate dielectric layer 210. The barrier layer BML may include, for example, titanium (Ti) and/or titanium nitride (TiN). A metal layer ML may be formed on the barrier layer BML. The metal layer ML may include, for example, at least one of tungsten (W) or cobalt (Co).

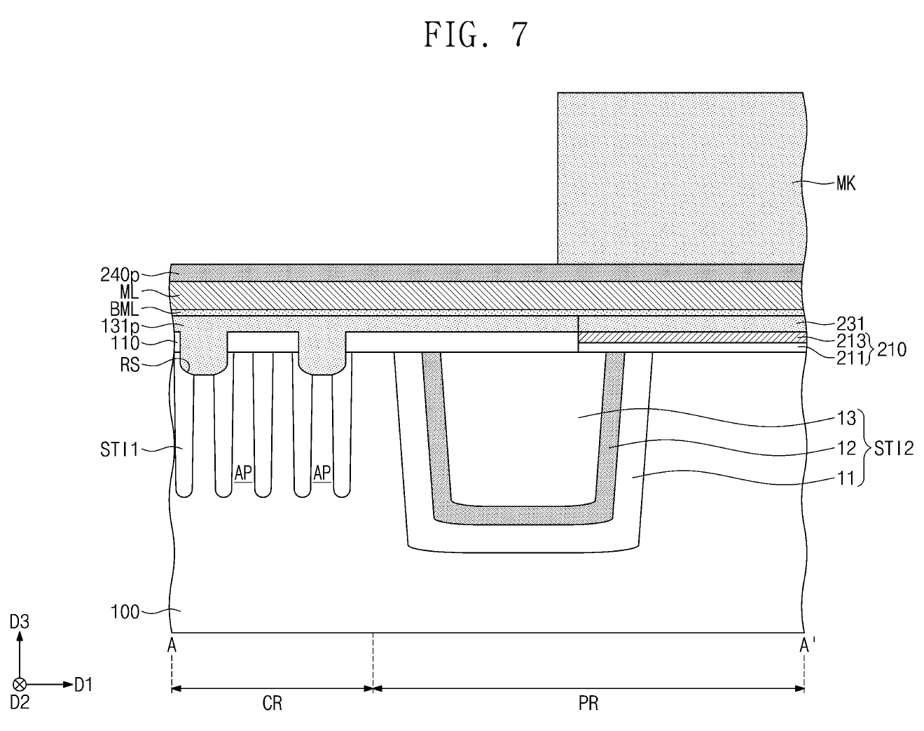

Referring to FIG. 7, a buffer layer 240p may be formed on the metal layer ML. The buffer layer 240p may entirely cover the top surface of the metal layer ML. The buffer layer 240p may include, for example, silicon nitride.

A mask pattern MK may be formed on the peripheral region PR of the substrate 100. For example, the mask pattern MK may cover a portion of the metal layer ML on the peripheral region PR.

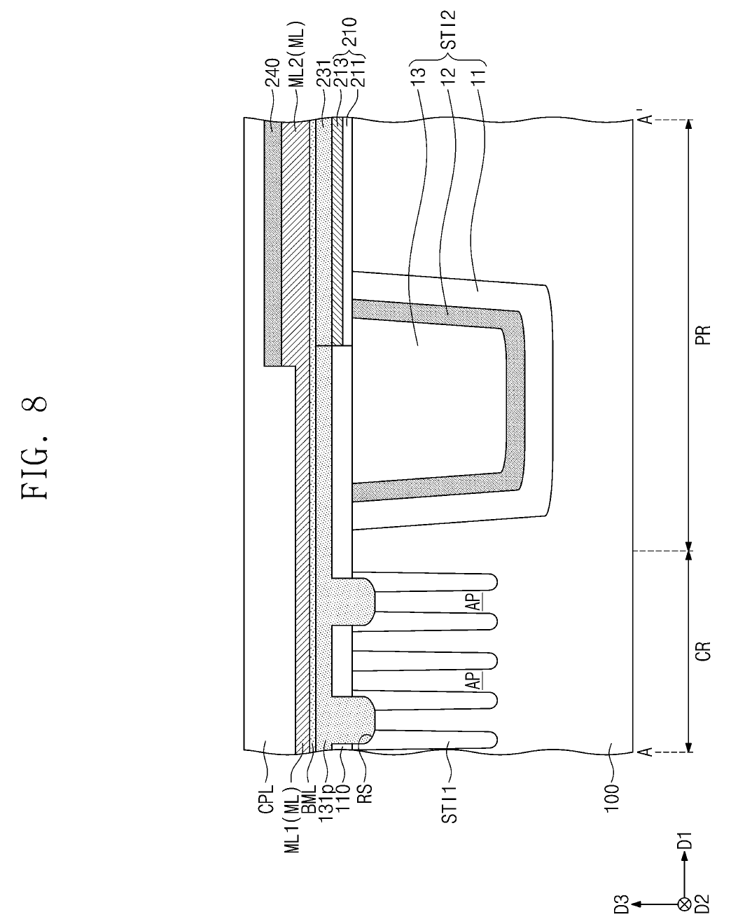

Referring to FIGS. 7 and 8, the metal layer ML may be etched by an etching process performed using the mask pattern MK as an etching mask. The metal layer ML may be partially etched to form a first metal layer ML1 and a second metal layer ML2 having different thicknesses from each other. The first metal layer ML1 and the second metal layer ML2 may have different thicknesses from each other. A thickness of the first metal layer ML1 may be smaller than a thickness of the second metal layer ML2. The first metal layer ML1 may cover the cell region CR and a portion of the peripheral region PR. The second metal layer ML2 may cover a remaining portion of the peripheral region PR. The first metal layer ML1 and the second metal layer ML2 may be connected to each other.

During the process of etching the metal layer ML, the buffer layer 240p may be etched together. A remaining portion of the buffer layer 240p may be referred to as a buffer pattern 240.

A capping layer CPL may be formed on the first metal layer ML1 and the second metal layer ML2. The capping layer CPL may cover the first metal layer ML1 and the buffer pattern 240. Forming the capping layer CPL may include, for example, depositing an insulating material and planarizing the insulating material. The capping layer CPL may include, for example, at least one of silicon oxide or silicon nitride.

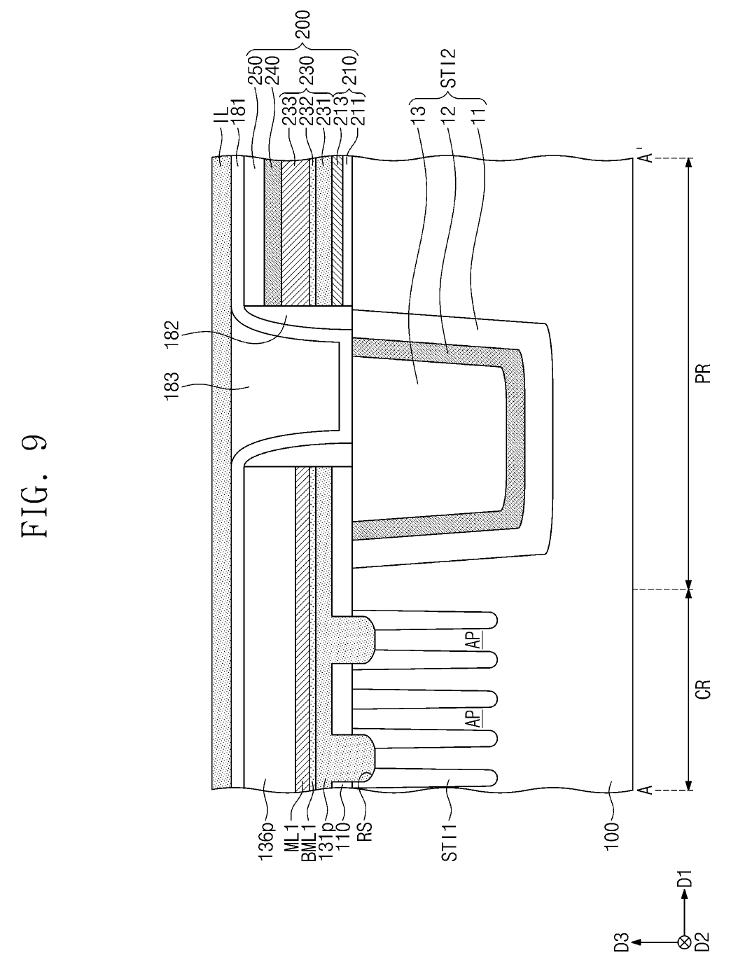

Referring to FIGS. 8 and 9, the first metal layer ML1 and the second metal layer ML2 on the cell region CR and the peripheral region PR may be separated. Separating the first metal layer ML1 and the second metal layer ML2 may include forming a second mask pattern on the peripheral region PR and performing a patterning process using the second mask pattern. After performing the patterning process, the second metal layer ML2 may be referred to as a peripheral metal pattern 233.

During the patterning process, the capping layer CPL, the barrier layer BML, the first preliminary conductive layer 131p, the peripheral conductive pattern 231, the peripheral gate dielectric layer 210, and the lower insulating layer 110 may be etched together. The capping layer CPL may be etched and separated into a first preliminary capping pattern 136p on the cell region CR and a peripheral capping pattern 250 on the peripheral region PR. The barrier layer BML may be etched and separated into a first barrier layer BML1 on the cell region CR and a peripheral barrier pattern 232 on the peripheral region PR. During the patterning process, a peripheral gate electrode 230 including the peripheral conductive pattern 231, the peripheral barrier pattern 232, and the peripheral metal pattern 233 may be formed on the peripheral region PR. During the patterning process, a peripheral gate structure 200 including the peripheral gate dielectric layer 210, the peripheral gate electrode 230, the buffer pattern 240, and the peripheral capping pattern 250 may be formed. A top surface (or upper surface) of the substrate 100 and a top surface (or upper surface) of the second device isolation layer STI2 on the peripheral region PR may be exposed during the patterning process.

Peripheral spacers 182 may be formed on sidewalls of the peripheral gate structure 200. A liner layer 181 covering sidewalls and top surfaces (or upper surfaces) of the peripheral spacers 182 and the peripheral gate structure 200 may be formed.

A filling insulating layer 183 may be formed to fill a space between the peripheral spacers 182. Forming the filling insulating layer 183 may include depositing an insulating material on the liner layer 181 and performing a planarization process to expose the liner layer 181. A preliminary interlayer insulating layer IL may be formed on the liner layer 181 and the filling insulating layer 183.

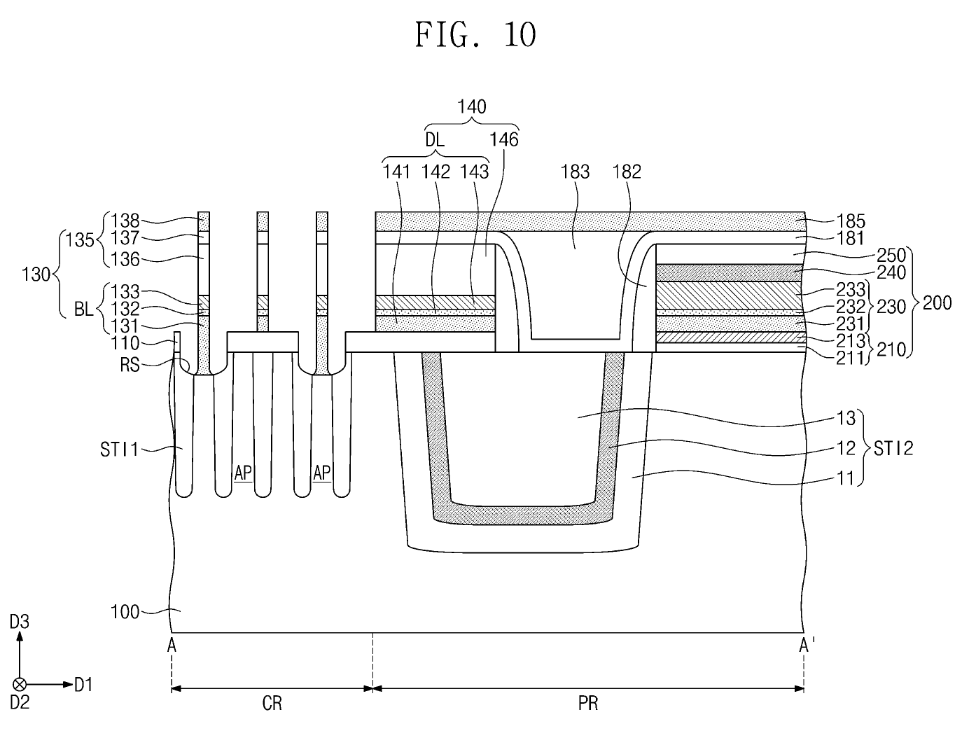

Referring to FIGS. 9 and 10, a patterning process may be performed on the cell region CR to pattern the first preliminary conductive layer 131p and the first metal layer ML1. A first conductive pattern 131 and a second conductive pattern 141 may be formed by patterning the first preliminary conductive layer 131p. A first metal pattern 133 and a second metal pattern 143 may be formed by patterning the first metal layer ML1. A first barrier pattern 132 and a second barrier pattern 142 may be formed by patterning the first barrier layer BML1. During the patterning process, bit lines BL including the first conductive pattern 131, the first metal pattern 133, and the first barrier pattern 132 may be formed. During the patterning process, a dummy line DL including the second conductive pattern 141, the second metal pattern 143, and the second barrier pattern 142 may be formed.

During the patterning process, the first preliminary capping pattern 136p, the liner layer 181, and the preliminary interlayer insulating layer IL may be patterned. The first preliminary capping pattern 136p may be patterned to form first capping patterns 136 and a dummy capping pattern 146. The liner layer 181 on the cell region CR may be patterned to form second capping patterns 137. The preliminary interlayer insulating layer IL may be patterned to form third capping patterns 138 on the cell region CR and to form an interlayer insulating layer 185 on the peripheral region PR. The patterning process may form a bit line capping pattern 135 including first to third capping patterns 136, 137, and 138.

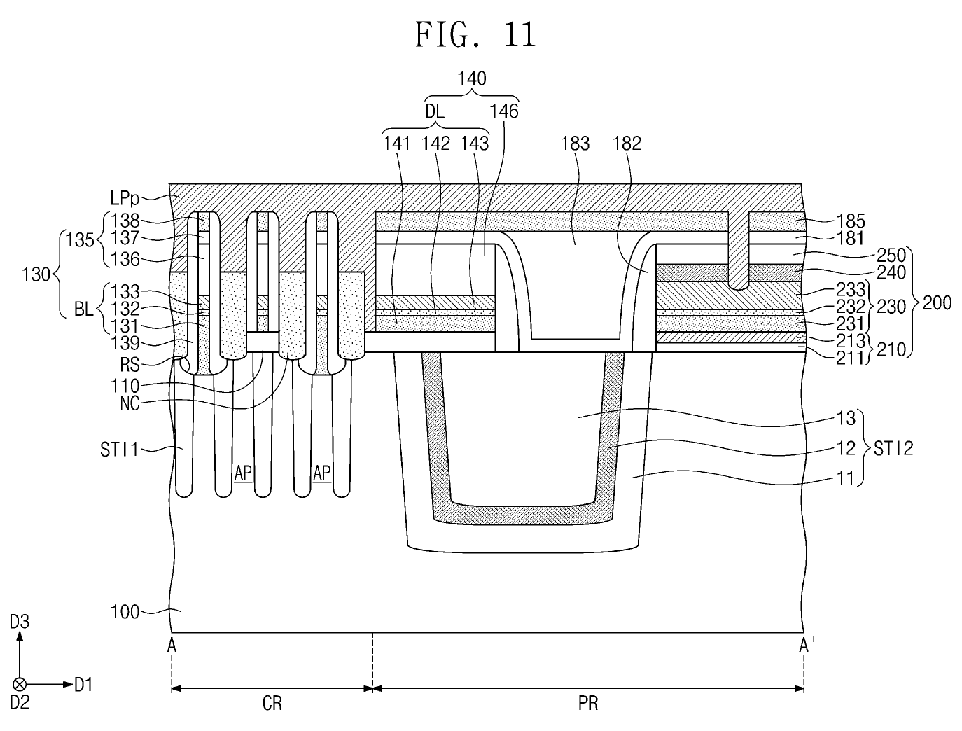

Referring to FIG. 11, bit line spacers 139 may be formed on the bit line BL and the sidewall of the bit line capping pattern 135. The bit line spacers 139 may fill the recess region RS.

Node contacts NC may be formed between the bit line spacers 139. A preliminary pad layer LPp may be formed on the node contacts NC. The preliminary pad layer LPp may include a conductive material. The preliminary pad layer LPp may cover the interlayer insulating layer 185 on the peripheral region PR. The preliminary pad layer LPp may be connected (e.g., electrically connected) to the peripheral gate structure 200.

Referring again to FIG. 3A, landing pads LP may be formed by etching the preliminary pad layer LPp with a photoresist layer on the cell region CR. A remaining portion of the preliminary pad layer LPp disposed on the peripheral region PR may be referred to as a conductive structure 195.

An upper insulating pattern 190 may be formed between the landing pads LP. The upper insulating pattern 190 may fill the space between the landing pads LP. For example, the upper insulating pattern 190 may include at least one of silicon oxide or silicon nitride. A data storage pattern DSP may be formed on the landing pads LP.

A semiconductor device according to embodiments may comprise a bit line on a cell region and a peripheral gate structure on a peripheral region. A thickness of a first metal pattern of the bit line may be smaller than a thickness of a peripheral metal pattern of the peripheral gate structure. Since the thickness of the first metal pattern is formed to be small, a parasitic capacitance of the bit line may be reduced. Accordingly, a ratio of a capacitance of a data storage pattern to the parasitic capacitance of the bit line may increase, so that sensing margin of the semiconductor device may be improved.

Since the thickness of the peripheral metal pattern is formed to be large, a resistance of the peripheral metal patterns may be reduced. Therefore, signal speed transmitted to the peripheral gate structure may be improved. Furthermore, a semiconductor device with improved electrical characteristics may be provided

While example embodiments have been particularly shown and described, it will be understood by one of ordinary skill in the art that variations in form and detail may be made therein without departing from the spirit and scope of the attached claims.

What is claimed is:

1. A semiconductor device, comprising:
a substrate comprising a cell region and a peripheral region;
an active pattern on the cell region of the substrate;
a bit line extending in a direction on the active pattern; and
a peripheral gate structure on the peripheral region,
wherein the bit line comprises:
a first conductive pattern connected to the active pattern; and
a first metal pattern on the first conductive pattern,
wherein the peripheral gate structure comprises:
a peripheral gate dielectric layer on the peripheral region of the substrate;
a peripheral conductive pattern on the peripheral gate dielectric layer; and
a peripheral metal pattern on the peripheral conductive pattern, and
wherein a thickness of the peripheral metal pattern is greater than a thickness of the first metal pattern.

2. The semiconductor device of claim 1, wherein the peripheral metal pattern and the first metal pattern comprise a same metal.

3. The semiconductor device of claim 1, wherein a distance between an upper surface of the peripheral metal pattern and a lower surface of the substrate is greater than a distance between an upper surface of the first metal pattern and the lower surface of the substrate.

4. The semiconductor device of claim 1, wherein the peripheral gate structure further comprises:
a peripheral capping pattern on the peripheral metal pattern; and
a buffer pattern between the peripheral metal pattern and the peripheral capping pattern.

5. The semiconductor device of claim 4, further comprising:
a conductive structure on the peripheral gate structure,
wherein the conductive structure comprises a protrusion penetrating the peripheral capping pattern and the buffer pattern and connected to the peripheral metal pattern.

6. The semiconductor device of claim 1, further comprising:
a dummy line between the bit line and the peripheral gate structure,
wherein the dummy line comprises:
a second conductive pattern between the first conductive pattern and the peripheral conductive pattern; and
a second metal pattern on the second conductive pattern,
wherein the dummy line is horizontally spaced apart from the bit line and the peripheral gate structure.

7. The semiconductor device of claim 6, wherein the thickness of the peripheral metal pattern is greater than a thickness of the second metal pattern.

8. The semiconductor device of claim 6, wherein the thickness of the first metal pattern is substantially equal to a thickness of the second metal pattern.

9. The semiconductor device of claim 1, further comprising:
a node contact on a sidewall of the bit line and connected to the active pattern;
a landing pad connected to the node contact; and
a data storage pattern on the landing pad,
wherein the data storage pattern is connected to the landing pad.

10. A semiconductor device, comprising:
a substrate comprising a cell region and a peripheral region;
an active pattern on the cell region of the substrate;
word lines extending across the active pattern in a first direction;
a bit line extending in a second direction intersecting the first direction on the word lines;
a peripheral gate structure on the peripheral region; and
a liner layer covering a sidewall and an upper surface of the peripheral gate structure,
wherein the peripheral gate structure comprises:
a peripheral gate dielectric layer on the peripheral region of the substrate;
a peripheral gate electrode on the peripheral gate dielectric layer;
a peripheral capping pattern on the peripheral gate electrode; and
a buffer pattern between the peripheral capping pattern and the peripheral gate electrode.

11. The semiconductor device of claim 10, wherein the peripheral gate electrode comprises a peripheral conductive pattern and a peripheral metal pattern on the peripheral conductive pattern, and
wherein the buffer pattern contacts an upper surface of the peripheral metal pattern.

12. The semiconductor device of claim 11,
wherein the bit line comprises:
a first conductive pattern extending in the second direction on the active pattern, and
a first metal pattern on the first conductive pattern, and
wherein a thickness of the peripheral metal pattern is greater than a thickness of the first metal pattern.

13. The semiconductor device of claim 10, further comprising:
a dummy line structure between the bit line and the peripheral gate structure,
wherein the dummy line structure comprises:
a dummy line between the bit line and the peripheral gate electrode, and
a dummy capping pattern on the dummy line, and
wherein an upper surface of the buffer pattern is at a lower level than an upper surface of the dummy capping pattern.

14. The semiconductor device of claim 13, wherein the upper surface of the dummy capping pattern is coplanar with an upper surface of the peripheral capping pattern.

15. The semiconductor device of claim 13, wherein a lower surface of the buffer pattern is at a higher level than an upper surface of the dummy line.

16. A semiconductor device, comprising:
a substrate comprising a cell region and a peripheral region;
an active pattern on the cell region of the substrate;
word lines extending across the active pattern in a first direction;
a bit line structure extending in a second direction intersecting the first direction on the word lines, the bit line structure comprising a bit line and a bit line capping pattern on the bit line;
a node contact connected to the active pattern;
a landing pad connected to the node contact; and
a peripheral gate structure on the peripheral region,
wherein the bit line comprises:
a first conductive pattern extending in the second direction on the active pattern; and
a first metal pattern on the first conductive pattern,
wherein the peripheral gate structure comprises:
a peripheral gate dielectric layer on the peripheral region of the substrate;
a peripheral conductive pattern on the peripheral gate dielectric layer;
a peripheral metal pattern on the peripheral conductive pattern;
a peripheral capping pattern on the peripheral metal pattern; and
a buffer pattern between the peripheral capping pattern and the peripheral metal pattern, and
wherein a thickness of the peripheral metal pattern is greater than a thickness of the first metal pattern.

17. The semiconductor device of claim 16, wherein the peripheral metal pattern and the first metal pattern comprise tungsten.

18. The semiconductor device of claim 16, further comprising:
a dummy line between the bit line and the peripheral gate structure; and
a dummy capping pattern on the dummy line,
wherein the dummy line comprises:
a second conductive pattern between the first conductive pattern and the peripheral conductive pattern; and
a second metal pattern on the second conductive pattern,
wherein the dummy line is horizontally spaced from the bit line and the peripheral gate structure, and
wherein the thickness of the peripheral metal pattern is greater than a thickness of the second metal pattern.

19. The semiconductor device of claim 18, wherein a thickness of the dummy capping pattern is greater than a thickness of the peripheral capping pattern.

20. The semiconductor device of claim 18, wherein the thickness of the first metal pattern is substantially the same as the thickness of the second metal pattern.
